(19) United States
(12) Patent Application Publication
(10) Pub. No.: US 2024/0153973 A1
(43) Pub. Date: May 9, 2024

(54) PACKAGING MODULE

(71) Applicant: TRIPLE WIN TECHNOLOGY(SHENZHEN) CO.LTD., Shenzhen (CN)

(72) Inventor: KUEI-FENG PENG, New Taipei (TW)

(21) Appl. No.: 17/993,527

(22) Filed: Nov. 23, 2022

(30) Foreign Application Priority Data
Nov. 3, 2022 (CN) 202211370866.2

(51) Int. Cl. H01L 27/146; H01L 23/00; H01L 23/367; H01L 23/498

(52) U.S. Cl. CPC H01L 27/14618; H01L 23/367; H01L 23/49822; H01L 23/49827; H01L 24/32; H01L 24/48; H01L 24/73; H01L 2224/32225; H01L 2224/48227; H01L 2224/73265

(57) ABSTRACT

A packaging module includes a circuit board, a chip, a radiation fin, and a light conducting member. The chip, the radiation fin, and the light conducting member are arranged on a same surface of the circuit board, the light conducting member and the circuit board enclosing a chamber containing the chip. The radiation fin surrounds the chip and is in contact with the light conducting. The circuit board includes a first through hole extending in a thickness direction of the circuit board and corresponding to the chip. In the packaging module, heat is transferred to the outside along two different directions, via the first through hole and via the radiation fin, improving heat dissipation efficiency.

### FIELD

The subject matter herein generally relates to a packaging module.

### BACKGROUND

Chips are used in many products, such as an electronic device. When the chip is in use, heat will be produced. In order to ensure reliable and continuing performance of the chip, the heat generated by the chip needs to be dissipated quickly.

### BRIEF DESCRIPTION OF THE DRAWINGS

Implementations of the present technology will now be described, by way of embodiment, with reference to the attached figures.

FIG. 1 is a cross-sectional view of a packaging module according to an embodiment of the present disclosure.

FIG. 2 is a cross-sectional view of a packaging module according to another embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. Some methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, directly or indirectly through intervening components, and is not necessarily limited to physical connections. The connection can be such that the objects are permanently connected or releasably connected. The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series, and the like.

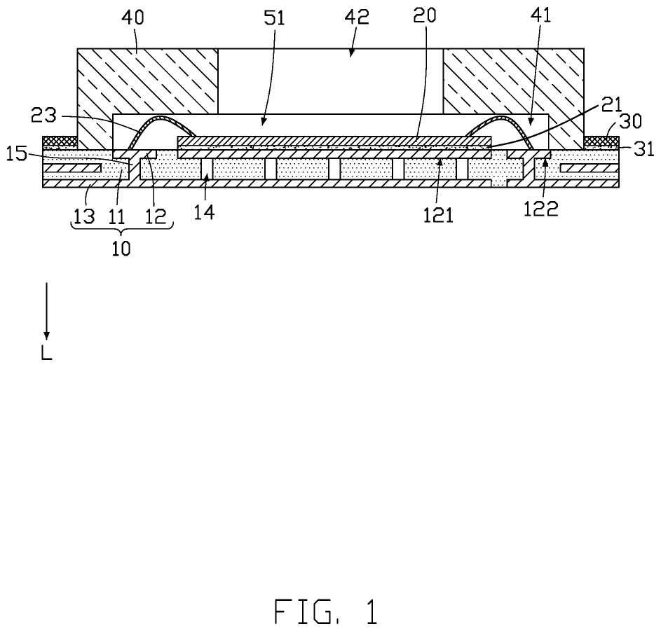

Referring to FIG. 1, a first embodiment of a packaging module 100 is illustrated. The packaging module 100 may a camera module. The camera module can be applied to an electronic device, such as a mobile phone, a wearable device, a vehicle, or a monitoring device.

The packaging module 100 includes a circuit board 10, a chip 20, a radiation fin 30, and a light conducting member 40. The chip 20, the radiation fin 30, and the light conducting member 40 are arranged on a same surface of the circuit board 10, the chip 20 is arranged between the light conducting member 40 and the circuit board 10, and the radiation fin 30 is in contact with the light conducting member 40.

The circuit board 10 includes a substrate layer 11, a first conductive wiring layer 12, and a second conductive wiring layer 13. The first conductive wiring layer 12 and the second conductive wiring layer 13 are arranged on opposite surfaces of the substrate layer 11. The substrate layer 11 is insulative and made of resin or the like. The first conductive wiring layer 12 and the second conductive wiring layer 13 are made of metal, such as copper.

The first conductive wiring layer 12 includes a chip pad 121 and a connection pad 122 spaced from each other. In this embodiment, there are two connection pads 122 which are located on opposite sides of the chip pad 121. The chip 12 is attached to the chip pad 121 through a first thermally conductive adhesive layer 21 and is electronically coupled with the connection pad 122 through a bonding wire 23.

The circuit board 10 defines a plurality of first through holes 14 penetrating the substrate layer 11 along a thickness direction L of the circuit board 10. The first through holes 14 are correspondingly positioned relative to the chip pad 121, and portions of the chip pad 121 are exposed in the first through holes 14. Each first through hole 14 is coupled with the chip pad 121 and the second conductive wiring layer 13. In this embodiment, an end of each first through hole 14 is covered by the chip pad 121, and the other end of each first through hole 14 is covered by the second conductive wiring layer 13. In other embodiments, the other end of each first through hole 14 may be exposed and not covered by the second conductive wiring layer 13. Two conductor structures 15 are arranged in the substrate layer 11. Each conductor structure 15 penetrates the substrate layer 11 and is electrically coupled with a corresponding connection pad 122 and the second conductive wiring layer 13, thereby electrically connecting the first conductive wiring layer 11 and the second conductive wiring layer 13.

The first thermally conductive adhesive layer 21 is made of silver paste or the like. A size of the chip pad 121 can be according to a desired size of the chip 20.

In some embodiments, thicknesses and wire widths of the first conductive wiring layer 12 and the second conductive wiring layer 13 are increased as needed, which facilitates heat dissipation from the circuit board 10.

A surface of the light conducting member 40 facing the circuit board 10 defines a groove 41. The groove 41 is covered by the circuit board 10 to form a first chamber 51, so the light conducting member 40 and the circuit board 10 cooperatively enclose the first chamber 51. The chip 20 is arranged in the first chamber 51. The light conducting member 40 further defines a second through hole 42 penetrating the light conducting member 40 in the thickness direction L. The second through hole 42 is in communication with the groove 41 and corresponds to the chip 20. The radiation fin 30 surrounds the light conducting member 40. A second thermally conductive adhesive layer 31 is sandwiched between the radiation fin 30 and the first conductive wiring layer 12.

In this embodiment, the chip 20 is an image sensor, and the light conducting member 40 is a lens holder. In practical applications, light can enter the chip 20 for imaging via the second through hole 42 of the lens holder.

In the packaging module 100, the circuit board 10 defines the first through holes 13 coupled between the chip pad 121 and the second conductive wiring layer 13, allowing heat generated by the chip 20 to be transferred to the outside along the thickness direction L, thereby achieving heat conduction in a longitudinal direction. At the same time, the radiation fin 30 is arranged on a surface of the circuit board 10, heat is further transferred to the radiation fin 30 through the first conductive wiring layer 12 along a direction vertical to the thickness direction L, thereby achieving heat conduction in a horizontal direction. Heat is thereby transferred to the outside along two different directions, thereby improving heat dissipation efficiency.

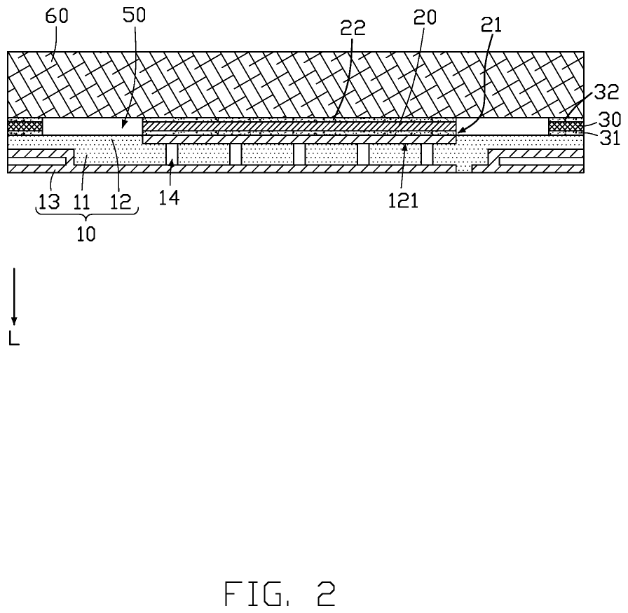

Referring to FIG. 2, a second embodiment of a packaging module 200 is illustrated. The packaging module 200 includes the circuit board 10, the chip 20, the radiation fin 30, and a radiator plate 60. The chip 20, the radiation fin 30, and the radiator plate 60 are arranged on a same side of the circuit board 10. The chip 20 and the radiation fin 30 are arranged on a surface of the circuit board 10 at intervals. The radiator plate 60 is arranged on a surface of the radiation fin 30 facing away from the circuit board 10. The chip 20 is arranged between the radiator plate 60 and the circuit board 10.

The circuit board 10 includes the substrate layer 11, the first conductive wiring layer 12, and the second conductive wiring layer 13. The first conductive wiring layer 12 and the second conductive wiring layer 13 are arranged on opposite surfaces of the substrate layer 11. The first conductive wiring layer 12 includes the chip pad 121, the chip 20 is attached to and the chip pad 121 through the first thermally conductive adhesive layer 21. The chip 20 is electrically coupled with the chip pad 121 through the first thermally conductive adhesive layer 121. The circuit board 10 defines the first through holes 14 penetrating the substrate layer 11 in the thickness direction L of the circuit board 10. Each first through hole 14 is coupled with the chip pad 121 and the second conductive wiring layer 13.

The radiation fin 30 surrounds the chip 20. The radiation fin 30, the circuit board 10, and the radiator plate 60 enclose a second chamber 50. The chip 20 is arranged in the second chamber 50. A side of the chip 20 facing away from the circuit board 10 is attached to a surface of the radiator plate 60 through the third thermally conductive adhesive layer 22.

The second thermally conductive adhesive layer 31 is sandwiched between the radiation fin 30 and the circuit board 10. A fourth thermally conductive adhesive layer 32 is sandwiched between the radiator plate 60 and the radiation fin 30.

The third thermally conductive adhesive layer 22 and the fourth thermally conductive adhesive layer 32 are made of silver paste or the like. The size of the chip pad 121 suits the size of the chip 20.

In the packaging module 200, the circuit board 10 defines the first through holes 13, the radiator plate 60 is arranged on a side of the chip 20 facing away from the circuit board 10, so that heat is transferred to the outside along opposite sides of the thickness direction L through the first through holes 13 and the radiator plate 60, and heat is further transferred to the outside along the direction vertical to the thickness direction L through the second chamber 50 and the radiation fin 30.

While the present disclosure has been described with reference to particular embodiments, the description is illustrative of the disclosure and is not to be construed as limiting the disclosure. Those of ordinary skill in the art can make various modifications to the embodiments without departing from the scope of the disclosure as defined by the appended claims.

What is claimed is:

1. A packaging module comprising:
a circuit board;
a light conducting member arranged on the circuit board, the light conducting member and the circuit board cooperatively enclosing a chamber;
a chip arranged in the chamber; and
a radiation fin located outside the chamber, surrounding the chip, and being in contact with the light conducting member;
wherein the light conducting member, the chip, and the radiation fin are arranged on a same surface of the circuit board, the circuit board comprising a first through hole extending in a thickness direction of the circuit board, the first through hole is correspondingly positioned relative to the chip.

2. The packaging module of claim 1, the circuit board further comprising a substrate layer, a first conductive wiring layer, and a second conductive wiring layer, wherein the substrate is sandwiched between the first conductive wiring layer and the second conductive wiring layer, the chip is arranged on and electrically coupled with the first conductive wiring layer, the first through hole is coupled between the first conductive wiring layer and the second conductive wiring layer.

3. The packaging module of claim 2, wherein the first conductive wiring layer comprises a chip pad and a connection pad, the chip is fixed to the chip pad and is electrically coupled with the connection pad through a bonding wire, the first through hole is coupled with the chip pad.

4. The packaging module of claim 3, wherein the chip is fixed to the chip pad through a thermally conductive adhesive layer.

5. The packaging module of claim 3, wherein a conductor structure is arranged in the substrate layer, the conductor structure is electrically coupled with the connection pad and the second conductive wiring layer.

6. The packaging module of claim 1, wherein a surface of the light conducting member facing the circuit board defines a groove, the circuit board covers the groove to form the chamber, the light conducting plate defines a second through hole communicating with the chamber, the second through hole is correspondingly positioned relative to the chip.

7. The packaging module of claim 1, wherein a thermally conductive adhesive layer is sandwiched between the radiation fin and the circuit board.

8. A packaging module comprising:
a circuit board;
a chip arranged on the circuit board;
a radiation fin arranged on the circuit board and surrounding the chip; and
a radiator plate arranged on a surface of the radiation fin facing away from the circuit board and surrounding the chip;
wherein the circuit board, the radiator plate, and the radiation fin cooperatively enclose a chamber, the chip is arranged in the chamber, the circuit board defines a through hole extending in a thickness direction of the circuit board, the first through hole is correspondingly positioned relative to the chip.

9. The packaging module of claim 8, the circuit board comprising a substrate layer, a first conductive wiring layer, and a second conductive wiring layer, wherein the substrate is sandwiched between the first conductive wiring layer and the second conductive wiring layer, the chip is arranged on and electrically coupled with the first conductive wiring layer, the first through hole is coupled between the first conductive wiring layer and the second conductive wiring layer.

10. The packaging module of claim 9, wherein the first conductive wiring layer comprises a chip pad, the chip is fixed to and electrically coupled with the chip pad.

11. The packaging module of claim 10, wherein the chip is fixed to the chip pad through a thermally conductive adhesive layer.

12. The packaging module of claim 8, wherein a thermally conductive adhesive layer is sandwiched between the radiation fin and the circuit board.

13. The packaging module of claim 12, wherein another thermally conductive adhesive layer is sandwiched between the radiation fin and the radiator plate.
